(19) United States
(12) Patent Application Publication
(10) Pub. No.: US 2025/0238919 A1
(43) Pub. Date: Jul. 24, 2025

(54) SYSTEM AND METHOD WITH MACHINE LEARNING FOR SEMICONDUCTOR WAFER DEFECT DETECTION

(71) Applicant: Samsung Electronics Co., Ltd., Suwon-si (KR)

(72) Inventors: Priyadarshini Panemangalore PAI, Bengaluru (IN); Prashant Pandurang SHINDE, Bengaluru (IN); Shashishekara Parampalli ADIGA, Bengaluru (IN)

(73) Assignee: Samsung Electronics Co., Ltd., Suwon-si (KR)

(21) Appl. No.: 19/029,069

(22) Filed: Jan. 17, 2025

(30) Foreign Application Priority Data
Jan. 19, 2024 (IN) 202441003888

(51) Int. Cl. G06T 7/00; G06T 3/4046; G06T 5/60; G06T 5/70

(52) U.S. Cl. CPC G06T 7/001; G06T 3/4046; G06T 5/60; G06T 5/70; G06T 2207/20081; G06T 2207/20084; G06T 2207/30148; G06T 2207/30168

(57) ABSTRACT

A method for training a second Machine Learning (ML) system to determine semiconductor wafer defects includes: receiving a first set of semiconductor wafer images for which defect detection failed in a first ML system; generating a first dataset based on the received first set of images and corresponding prediction results of the first ML system; modifying the images in the first dataset using predefined image adjustment parameters to generate a second set of images; identifying, using the first ML system, defects in the second set of images; assigning ground truths to the second set of images based on the identified defects; generating a second dataset based on the first dataset, the second set of images, and the ground truths associated therewith; and training, based on the generated second dataset, the second ML system to determine semiconductor wafer defects.

### CROSS-REFERENCE TO RELATED APPLICATIONS

This application claims the benefit under 35 USC § 119(a) of Indian patent application Ser. No. 20/244,1003888, filed on Jan. 19, 2024, in the Indian Patent Office, the entire disclosure of which is incorporated herein.

### BACKGROUND

### 1. Field

The present disclosure generally relates to the defect detection in semiconductor wafers, and more particularly relates to training a machine learning system to determine defects in semiconductor wafers.

### 2. Description of Related Art

The semiconductor industry is increasingly leveraging artificial intelligence (AI)-powered defect detection methodologies to optimize product yield and reduce manufacturing costs. With technology nodes diminishing in size, there is a growing need for high-precision defect detection techniques. Over the years, various approaches, including defect identification, bounding box localization, and size estimation methods, have been developed. However, the performance of these approaches largely relies on the selection of appropriate machine learning or deep learning (ML/DL) architectures along with input data.

### SUMMARY

This summary is provided to introduce a selection of concepts, in a simplified format, that are further described in the detailed description of the invention. This summary is neither intended to identify essential inventive concepts of the invention nor is it intended for determining the scope of the invention.

In one general aspect, a method for training a second Machine Learning (ML) system to determine semiconductor wafer defects includes: receiving a first set of semiconductor wafer images for which defect detection failed in a first ML system; generating a first dataset based on the received first set of images and corresponding prediction results of the first ML system; modifying the images in the first dataset using predefined image adjustment parameters to generate a second set of images; identifying, using the first ML system, defects in the second set of images; assigning ground truths to the second set of images based on the identified defects; generating a second dataset based on the first dataset, the second set of images, and the ground truths associated therewith; and training, based on the generated second dataset, the second ML system to determine semiconductor wafer defects.

The predefined image adjustment parameters may include an image enhancement parameter or an image degradation parameter.

The predefined image adjustment parameter may include a noise adjustment parameter, a resolution adjustment parameter, or a blurriness adjustment parameter, and modifying the images in the first dataset may include: performing, on each of the images in the first set of images, at least one of addition of noise, removal of noise, resolution upscaling, resolution down-scaling, or an attribute change.

The method may include: determining, by applying the second ML system to the second dataset, a set of image corrections.

The method may further include: training the second ML system based on a third set of semiconductor wafer images, and the third set of images may be images for which the first ML system successfully detected semiconductor wafer defects.

The method may include: modifying the third set of images using predefined image adjustment parameters; generating a third dataset including the modified third set of images and corresponding ground truths; and training the second ML system based on the generated third dataset.

The method may include: generating a set of image modification guidelines based on the set of image corrections, using the predefined image adjustment parameters with respect to one or more characteristics of the images and assigned ground truths.

The method may include: determining, using the second ML system, semiconductor wafer defects in the first set of images as modified based on the generated set of image corrections.

The method may include: performing root cause analysis to determine a reason the first ML system failed in defect detection, in the first set of images, based on a defect size threshold and a noise level threshold.

In another general aspect, a system for training a second Machine Leaning (ML) system to determine defects in a semiconductor wafer includes: one or more processors; a memory coupled with the one or more processors and storing instructions configured to cause the one or more processors to: receive a first set of semiconductor wafer images for which defect detection failed in a first ML system; generate a first dataset based on the received first set of images and corresponding prediction results of the first ML system; modify the images in the first dataset using predefined image adjustment parameters to generate a second set of images; identify, using the first ML system, defects in the second set of images; assign ground truths to the second set of images based on the identified defects; generate a second dataset based on the first dataset, the second set of images, and the ground truths associated therewith; and train, based on the generated second dataset, the second ML system to determine semiconductor wafer defects.

The predefined image adjustment parameters may include an image enhancement parameter or an image degradation parameter.

The predefined image adjustment parameters may include a noise adjustment parameter, a resolution adjustment parameter, or a blurriness adjustment parameter, and for modifying the images in the first dataset includes, the instructions may be further configured to cause the one or more processors to: perform, on each of the images in the first set of images, at least one of addition of noise, removal of noise, resolution upscaling, resolution down-scaling, or an attribute change.

The instructions may be further configured to cause the one or more processors to: determine, by applying the second ML system to the second dataset, a set of corrections.

The instructions may be further configured to cause the one or more processors to: train the second ML system based on a third set of semiconductor wafer images, wherein the third set of images are images for which the first ML system successfully detected semiconductor wafer defects.

The instructions may be further configured to cause the one or more processors to: modify the third set of images using predefined image adjustment parameters; generate a third dataset including the modified third set of images and corresponding ground truths; and train the second ML system based on the generated third dataset.

The instructions may be further configured to cause the one or more processors to: generate a set of image modification guidelines based on the set of image corrections, using the predefined image adjustment parameters with respect to one or more characteristics of the images and assigned ground truths.

The instructions may be further configured to cause the one or more processors to: determine, using the second ML system, semiconductor wafer defects in the first set of images as modified based on the generated set of image corrections.

The instructions may be further configured to cause the one or more processors to: perform root cause analysis to determine a reason the first ML system failed in defect detection, in the first set of images, based on a defect size threshold and a threshold noise level.

Other features and aspects will be apparent from the following detailed description, the drawings, and the claims.

### BRIEF DESCRIPTION OF THE DRAWINGS

FIG. 1A depicts a conventional approach for defect detection.

FIG. 1B depicts another conventional approach for defect detection.

FIG. 2 depicts a system for training a second ML system to determine semiconductor wafer defects, according to one or more embodiments.

FIG. 3 depicts operations among components of a system for training the second ML system, according to one or more embodiments.

FIG. 4 depicts a method for training the second ML system, according to one or more embodiments.

Throughout the drawings and the detailed description, unless otherwise described or provided, the same or like drawing reference numerals will be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

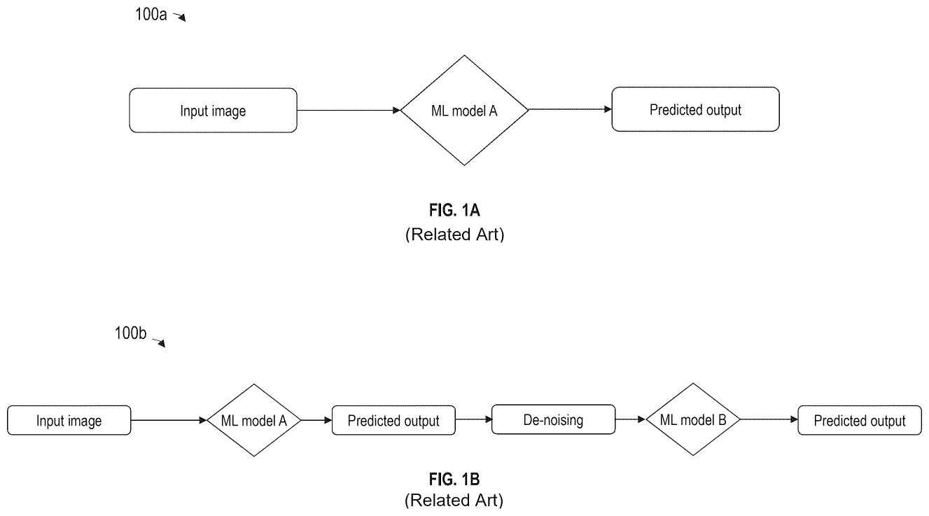

FIG. 1A shows a flow diagram 100a of a conventional approach for defect detection. Conventional approaches for defect detection use image pre-processing techniques to provide limited/constrained operation conditions. In the conventional approach, when an ML model A is implemented, an output predicted from an input image is a one-shot detection, that is, the defects are either detected (considered as ‘hit’) or not detected (considered as ‘miss’). Once defect detection misses a defect there is no further chance to detect the missed defect.

While progress has been made in the optimization of ML/DL architectures, their efficacy remains constrained to a certain extent. ML models may lack accuracy when input data such as defect size, noise level, and resolution have high heterogeneity.

FIG. 1B shows a flow diagram 100b depicting a system for defect detection. The system de-noises input images and uses another ML model, for example, ML model B to detect defects that were missed during detection by ML model A. However, there are several limitations.

First, the currently available techniques consider only images on which defect was identified, thereby missing false negatives, or missed predictions. Second, currently available techniques only recommend de-noising or resolution enhancement without accounting for input corrections that may be needed for accurate predictions.

Moreover, manually identifying solutions for every image is labor-intensive and impractical. In general, semiconductor device fabrication involves steps such as applying a film on a semiconductor substrate (or wafer), smoothing the film, forming the film into a photoresist pattern having electrical characteristics, and removing impurities on the semiconductor wafer. Finally, the fabricating process typically includes inspecting the semiconductor wafer to identify defects in the pattern formed on the semiconductor wafer.

During the fabrication process, defects such as particulate contamination and pattern defects may occur. Such defects impact the operating characteristics of the semiconductor wafer and the efficiency of production. If left undetected during the inspection step, defects may cause faults in the semiconductor device manufactured from the semiconductor wafer.

Embodiments described herein may identify a reason for defect detection failure. Root cause analysis of defect detection failure cases may be used to determine if any corrective measures can be applied to improve defect detection accuracy.

To these ends, techniques for training a second machine learning (ML) system may enable detection of defects in a semiconductor wafer where using only a first ML system may fail to detect the defects.

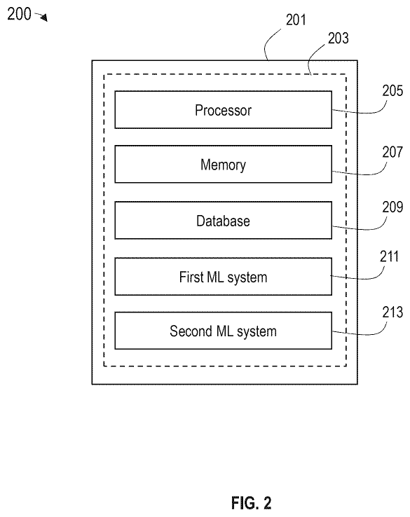

FIG. 2 depicts a block diagram 200 of a system 203 for training the second ML system 213 to determine semiconductor wafer defects, according to embodiments of the present disclosure. The system 203 may be implemented in a device 201. In The system 203 may be implemented in a distributed manner in more than one user device. The system 203 may also be implemented in an automated defect review system that accompanies advanced semiconductor wafer imaging for inspection. The system 203 may be a part of a standalone software or a host of models that can be deployed based on requirement.

The system 203 includes a processor 205, a memory 207, a database 209, a first ML system 211, and the second ML system 213 coupled with each other.

In an example, the processor(s) 205 may be a single processing unit or a number of units (possibly of diverse types), any of which may include multiple computing units. The processor 205 may be implemented as one or more microprocessors, microcomputers, microcontrollers, digital signal processors, central processing units, logical processors, virtual processors, state machines, logic circuitries, and/or any devices that manipulate signals based on operational instructions. Among other capabilities, the processor 205 is configured to fetch and execute computer-readable instructions and data stored in memory 207.

The memory 207 may include any non-transitory computer-readable medium known in the art including, for example, volatile memory or Random Access Memory (RAM) 205, such as static random access memory (SRAM) and dynamic random access memory (DRAM), and/or non-volatile memory, such as read-only memory (ROM), erasable programmable ROM, flash memories, hard disks, optical disks, and magnetic tapes.

Some operations of the system 203 may be implemented through an AI model. A function associated with AI may be performed through the non-volatile memory, the volatile memory, and the processor.

The processor may include one or more processors, which may be a general purpose processor, such as a central processing unit (CPU), an application processor (AP), or the like, a graphics-only processing unit such as a graphics processing unit (GPU), a visual processing unit (VPU), and/or an AI-dedicated processor such as a neural processing unit (NPU).

The processor controls the processing of the input data in accordance with a predefined operating rule or artificial intelligence (AI) model stored in the non-volatile memory and the volatile memory. The predefined operating rule or artificial intelligence model is provided through training or learning.

The aforementioned learning may include applying a learning technique to pieces of learning data to form a predefined operating rule or AI model of a desired characteristic. The learning may be performed in a device itself in which the AI model is implemented, and/or may be implemented through a separate server/system.

The AI model may consist of neural network layers. Each layer has weight values and performs a layer operation through calculation of a previous layer and an operation of weights. Examples of neural networks include but are not limited to, convolutional neural network (CNN), deep neural network (DNN), recurrent neural network (RNN), restricted Boltzmann Machine (RBM), deep belief network (DBN), bidirectional recurrent deep neural network (BRDNN), generative adversarial networks (GAN), and deep Q-networks, or combinations thereof.

The learning technique is a method for training a predetermined target device (for example, a robot) using learning data to cause, allow, or control the target device to make a determination or prediction. Examples of learning techniques include, but are not limited to, supervised learning, unsupervised learning, semi-supervised learning, or reinforcement learning.

The processor may perform a pre-processing operation on the data to convert the data into a form appropriate for use as an input for the artificial intelligence model. The artificial intelligence model may be obtained by training. Here, “obtained by training” means that a predefined operation rule or artificial intelligence model configured to perform a desired feature (or purpose) is obtained by training a basic artificial intelligence model with multiple pieces of training data by a training technique. The artificial intelligence model may include neural network layers. Each of the neural network layers includes weight values and performs neural network computation by computation between a result of computation by a previous layer and the weight values.

The database 209 may include one or more database repositories for storing data, such as sets of images and datasets used during the training of the second ML system 213.

Both the first ML system 211 and the second ML system 213 may be predefined and distinct machine learning-based models for identifying and detecting defects in the semiconductor wafers.

In some embodiments, the second ML system 213 is trained to determine corrective actions that can be performed on input images corresponding to a semiconductor wafer such that defects within the input images can be accurately detected. The input images may be provided as-is (i.e., without correction) to the first ML system 211, and the first ML system 211 may have failed to detect defects in the input images. Therefore, the input images are the images, with one or more defects, which are provided as an input to train the ML models/systems for defect detection, as discussed herein, during the training phase. Further, one or more input images may be provided as an input to the trained ML models/systems during the inference phase to detect defects therein.

A machine learning approach may be used for automating failure analysis of images on which desirable wafer defect detection could not be achieved (i.e., defect detection failure). Further, corrective actions to be performed on the input images may be determined. Guidelines may be generated to guide modification of the input images based on the determined corrective actions.

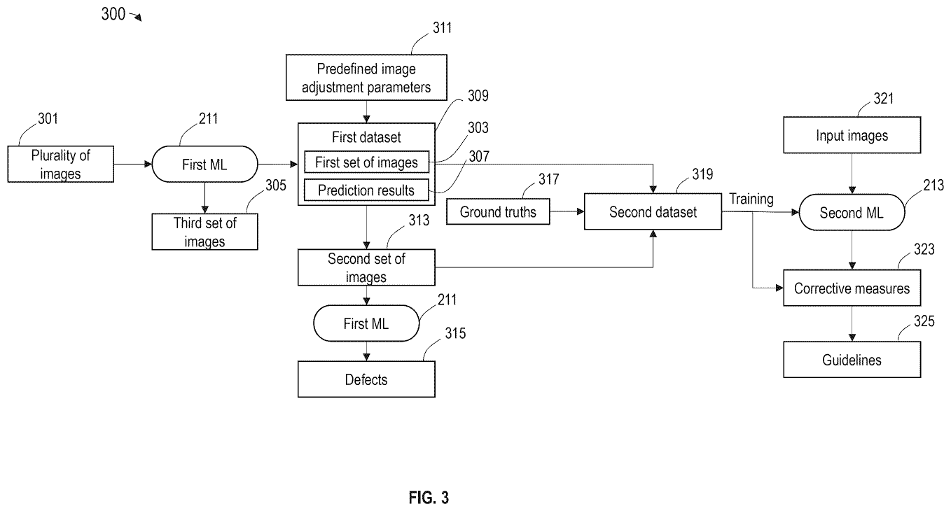

Overall operation of the system 203 for training the second ML system 213 to detect defects in images of semiconductor wafers is described next with reference to FIG. 3.

FIG. 3 shows a diagram 300 depicting the flow of operations among components of the system 203 for training the second ML system 213, according to one or more embodiments.

Input images 301 are provided as input to the first ML system 211. The images 301 may be of one or more semiconductor wafers.

Based on applying the first ML system 211 to the input images 301, a first set of images 303 and a third set of images 305 may be determined. The first set of images 303 are those of the input images for which the first ML system 211 failed to detect any defect. The third set of images 305 are the input images for which the first ML system 211 successfully detected a semiconductor wafer defect.

A first dataset 309 may be generated based on the inferences performed on the input images 301 that determined the first set of images 303; the first dataset 309 may include the first set of images 303 and corresponding prediction results 307 of the first ML system 211. The prediction results 307 may include correct, incorrect, and missed defect detection.

The images in the first dataset 309 may be modified using predefined image adjustment parameters 311 to generate a second set of images 313. The predefined image adjustment parameters may include an image enhancement parameter and/or an image degradation parameter. The predefined image adjustment parameters may include parameters to control modification of noise, resolution, and/or blurriness.

Modifying the images in the first dataset 309 (i.e., the first set of images 303) may include, for each image in the first dataset 309, adding noise, removing noise, resolution upscaling, resolution down-scaling, blurring/deblurring, and/or changing an attribute (e.g., contrast, brightness, or the like). In some implementations a same image may be upgraded and degraded, resulting in two images for the second set of images 313. In an implementation, the images are modified such that images are subjected to at least de-noising, correction, and/or resolution enhancement. The second set of images 313 includes the modified images of the images in the first set of images 306. The images in the second set of images 313 may have, respectively associated therewith, indications of which modifications they were subjected to.

The first ML system 211 is also applied to the images in the second set of images 313 to detect defects 315 therein. The detection of the defects 315 by the first ML system 211 provides an indication that the first set of images 303 contains image data indicating defects that could not be detected by the first ML system 211 (when first applied to the input images) due to unsuitable image quality, i.e., images that can be upgraded or degraded to become suitable for defect detection. In sum, when the non-defect-detection first set of images 303 was subjected to modifications and the resulting second set of images 313 (i.e., the modified first set of images) were inputted to the first ML system 211, the first ML system 211 successfully detected the defects 315.

Ground truths 317 associated, respectively, with the images in the second set of images 313 are assigned to corresponding images based on the more identified defects 315. The ground truths 317 associated with the second set of images 313 refer to information related to the quality of images that can be used as a benchmark reference to determine the suitability of image quality for defect detection. The ground truth in defect detection refers to the number, nature, location, type etc. of defects that are actually present in the image of a semiconductor wafer (e.g., as determined by prior or manual verification). For training the second ML model 213 for extraction of image modification/correction rules that lead to accurate defect prediction, images with enhancement and/or degradation and corresponding predictions using the first ML model are used. The ground truth in the context of the second ML model 213 is the actual prediction obtained using the first ML model for each of the original/enhanced/degraded set of images.

Once the ground truths 317 are assigned, a second dataset 319 is generated based on the first dataset 309, the second set of images 313, and the ground truths 317 associated therewith.

The second dataset 319 may be used to train the second ML system 213 to determine defects in images of semiconductor wafers and to infer image corrections that facilitate defect detection when applied to images. Alternatively/additionally, the second ML system 213 may be trained on the third set of images 305.

A root cause analysis may be performed to determine the reason the first ML system 211 failed in defect detection on the first set of images. A review system included in the system 300 or provided separately from the system 300 may perform the root cause analysis. For example, if the size of the defect is below a predetermined threshold SL, then beyond a specific noise level threshold NH, the defect may not be detectable, or the location of the defect may not be identified. In some embodiments, the reasons may be deduced based on decision trees. The decision trees may perform feature selection or variable screening and can be used for both categorical and numerical data. Furthermore, the decision trees may be used to handle problems with multiple results or outputs.

Therefore, in some embodiments, if, in an input image, the first ML system detected the presence of a defect but could not identify the location and the noise level is below NH, the review system may determine that the obtained most likely cause of undesirable/failed defect detection is defect size.

After training on the second dataset 319, the second ML system 213 becomes capable of determining/inferring a set of corrective actions 323 (image adjustments) to be performed on input images 321 of other/new semiconductor wafers based on the second dataset 319. Based on the corrective actions, the second ML system 213 or the review system generates a set of guidelines 325 to modify input images using the one or more predefined image adjustment parameters (e.g., values for the adjustment parameters) with respect to one or more characteristics of the images and ground truths. In some embodiments, the corrective actions may be particular image modifications to be applied (e.g., denoising or resizing), and the guidelines 325 may be values for the particular modifications (e.g., a denoise level or an image size).

Further, the trained second ML system 213 may be applied to the first set of images 303 to determine/infer semiconductor wafer defects from the first set of images based as modified according to the generated set of guidelines.

In an embodiment, when the second ML system 213 is trained based on the third set of images 305, the third set of images is modified using one or more predefined image adjustment parameters, and a third dataset is generated including the modified third set of images and corresponding ground truths, and the second ML system 213 is trained based on the third dataset. The above described operation may be performed to degrade images for which defect detection was successful (e.g., the initial detection step), and the training the second ML system 213 using the degraded images.

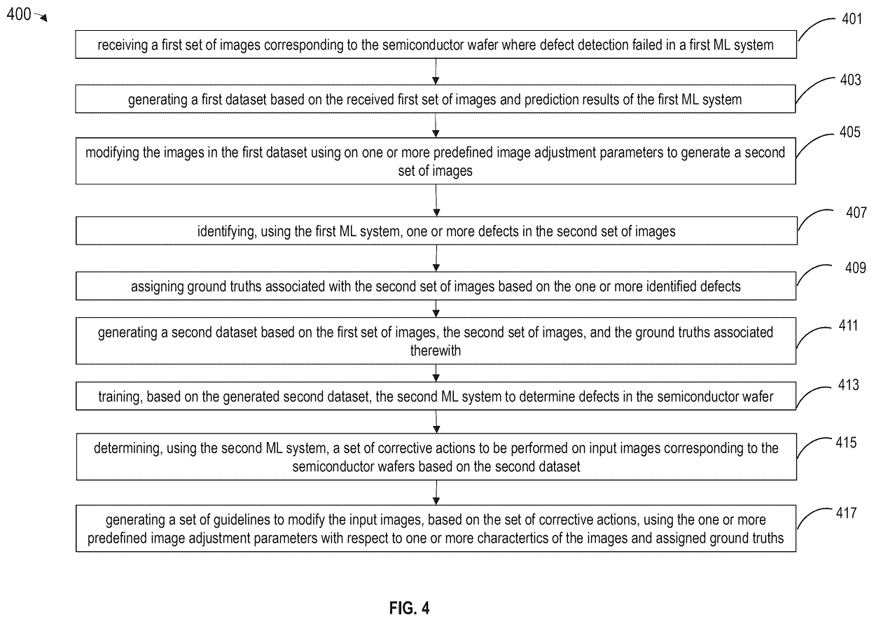

The method 400 for training the second ML system 213 to determine defects in the semiconductor wafer is now described below in conjunction with FIG. 4.

FIG. 4 depicts the method 400 for training the second ML system 213, according to one or more embodiments. The method 400 includes a series of operations 401 through 417 executed by one or more components of the system 203, in particular the processor 205.

At step 401, the processor 205 receives the first set of images corresponding to semiconductor wafer defect detection failure in the first ML system 211.

At step 403, the processor 205 generates the first dataset based on the received first set of images and prediction results of the first ML system 211.

At step 405, the processor 205 modifies the images in the first dataset using one or more predefined image adjustment parameters to generate a second set of images. The one or more predefined image adjustment parameters may include an image enhancement parameter and/or an image degradation parameter. The predefined image adjustment parameters may include a noise parameter, a resolution parameter, and/or a blurriness parameter, as non-limiting examples. Modifying the images in the first dataset may include adding noise, removing noise, resolution upscaling, resolution down-scaling, and/or an attribute change on the each of the images in the first set of images.

At step 407, the processor 205 identifies, using the first ML system, one or more defects in the second set of images.

At step 409, the processor 205 assigns ground truths associated with the second set of images based on the one or more identified defects.

At step 411, the processor 205 generates the second dataset based on the first dataset, the second set of images, and the ground truths associated therewith.

At step 413, the processor 205 trains, based on the generated second dataset, the second ML system to determine defects in the semiconductor wafer (and corrective measures/guidelines).

In some embodiments, the processor 205 may train the second ML system based on a third set of semiconductor wafer images (from among the first set of images), where the third set of images includes images for which the first ML system successfully detected a semiconductor wafer defect. In such embodiments, the processor 205 may modify the third set of images using one or more predefined image adjustment parameters, generate the third dataset including the modified third set of images and corresponding ground truths, and train the second ML system based on the generated third dataset.

At step 415, the processor 205 determines, using the second ML system, a set of corrective actions to be performed on input images corresponding to the semiconductor wafers based on the second dataset.

At step 417, the processor 205 generates a set of guidelines to modify the input images, based on the set of corrective actions, using the one or more predefined image adjustment parameters with respect to one or more characteristics of the images and assigned ground truths.

In some embodiments, the processor 205 determines, using the second ML system, semiconductor wafer defects from the first set of images based on the generated set of guidelines.

In some embodiments, the processor 205 performs root cause analysis to determine the reason the first ML system (211) failed in defect detection based on a first threshold associated with the size of the defects, and a second threshold associated with noise level in the first set of images.

At least by virtue of the aforesaid, implementations of the subject matter presented herein may provide advantages such as:

(1) Enabling large-scale failure analysis of wafer defect detection input samples to be performed without extensive requirement of manual intervention.

(2) Recommending a possible or available course of actions (e.g., equipment to replace/repair, alteration of a manufacturing step, etc.) based on failure analysis, thereby providing enhanced wafer defect detection.

(3) Deriving guidelines for recommending enhancement steps using machine learning/deep learning.

Some of the methods described in the embodiments herein provide a technique for recommending input enhancement to improve wafer defect detection on input images for which defect detection could not be obtained in the first attempt.

Thus, the methods described herein may address the issue of detecting defects where defect detection approaches have failed to predict the desirable outcome because the inputs needed further enhancement/processing.

The methods described herein use various deep learning enhancement models for input image improvement.

The computing apparatuses, the electronic devices, the processors, the memories, the image sensors, the displays, the information output system and hardware, the storage devices, and other apparatuses, devices, units, modules, and components described herein with respect to FIGS. 1-4 are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-4 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROM, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. A method for training a second Machine Learning (ML) system to determine semiconductor wafer defects, the method comprising:
receiving a first set of semiconductor wafer images for which defect detection failed in a first ML system;
generating a first dataset based on the received first set of images and corresponding prediction results of the first ML system;
modifying the images in the first dataset using predefined image adjustment parameters to generate a second set of images;
identifying, using the first ML system, defects in the second set of images;
assigning ground truths to the second set of images based on the identified defects;
generating a second dataset based on the first dataset, the second set of images, and the ground truths associated therewith; and
training, based on the generated second dataset, the second ML system to determine semiconductor wafer defects.

2. The method of claim 1, wherein the predefined image adjustment parameters comprise an image enhancement parameter or an image degradation parameter.

3. The method as claimed in claim 1, wherein the predefined image adjustment parameters comprise a noise adjustment parameter, a resolution adjustment parameter, or a blurriness adjustment parameter, and wherein modifying the images in the first dataset comprises:
performing, on each of the images in the first set of images, at least one of addition of noise, removal of noise, resolution upscaling, resolution down-scaling, or an attribute change.

4. The method of claim 1, comprising:
determining, by applying the second ML system to the second dataset, a set of image corrections.

5. The method of claim 1, further comprising:
training the second ML system based on a third set of semiconductor wafer images, wherein the third set of images are images for which the first ML system successfully detected semiconductor wafer defects.

6. The method of claim 5, comprising:
modifying the third set of images using predefined image adjustment parameters;
generating a third dataset including the modified third set of images and corresponding ground truths; and
training the second ML system based on the generated third dataset.

7. The method of claim 4, comprising:
generating a set of image modification guidelines based on the set of image corrections, using the predefined image adjustment parameters with respect to one or more characteristics of the images and assigned ground truths.

8. The method of claim 7, comprising:
determining, using the second ML system, semiconductor wafer defects in the first set of images as modified based on the generated set of image corrections.

9. The method of claim 1, comprising:
performing root cause analysis to determine a reason the first ML system failed in defect detection, in the first set of images, based on a defect size threshold and a noise level threshold.

10. A system for training a second Machine Leaning (ML) system to determine defects in a semiconductor wafer, the system comprising:
one or more processors;
a memory coupled with the one or more processors and storing instructions configured to cause the one or more processors to:
receive a first set of semiconductor wafer images for which defect detection failed in a first ML system;
generate a first dataset based on the received first set of images and corresponding prediction results of the first ML system;
modify the images in the first dataset using predefined image adjustment parameters to generate a second set of images;
identify, using the first ML system, defects in the second set of images;
assign ground truths to the second set of images based on the identified defects;
generate a second dataset based on the first dataset, the second set of images, and the ground truths associated therewith; and
train, based on the generated second dataset, the second ML system to determine semiconductor wafer defects.

11. The system of claim 10, wherein the predefined image adjustment parameters comprises an image enhancement parameter or an image degradation parameter.

12. The system of claim 10, wherein the predefined image adjustment parameters comprise a noise adjustment parameter, a resolution adjustment parameter, or a blurriness adjustment parameter, and wherein for modifying the images in the first dataset comprises, the instructions are further configured to cause the one or more processors to:
perform, on each of the images in the first set of images, at least one of addition of noise, removal of noise, resolution upscaling, resolution down-scaling, or an attribute change.

13. The system of claim 10, wherein the instructions are further configured to cause the one or more processors to:
determine, by applying the second ML system to the second dataset, a set of corrections.

14. The system of claim 10, wherein the instructions are further configured to cause the one or more processors to:
train the second ML system based on a third set of semiconductor wafer images, wherein the third set of images are images for which the first ML system successfully detected semiconductor wafer defects.

15. The system of claim 14, wherein the instructions are further configured to cause the one or more processors to:
modify the third set of images using predefined image adjustment parameters;
generate a third dataset including the modified third set of images and corresponding ground truths; and
train the second ML system based on the generated third dataset.

16. The system of claim 13, wherein the instructions are further configured to cause the one or more processors to:
generate a set of image modification guidelines based on the set of image corrections, using the predefined image adjustment parameters with respect to one or more characteristics of the images and assigned ground truths.

17. The system of claim 16, wherein the instructions are further configured to cause the one or more processors to:
determine, using the second ML system, semiconductor wafer defects in the first set of images as modified based on the generated set of image corrections.

18. The system of claim 10, wherein the instructions are further configured to cause the one or more processors to:
perform root cause analysis to determine a reason the first ML system failed in defect detection, in the first set of images, based on a defect size threshold and a threshold noise level.
